(19) United States
(12) Patent Application Publication
(10) Pub. No.: US 2010/0279228 A1
(43) Pub. Date: Nov. 4, 2010

(54) ORGANO-METALLIC HYBRID MATERIALS FOR MICRO- AND NANOFABRICATION

(75) Inventors: Cristina Davis, Davis, CA (US); Farrokh Yahgmaie, Davis, CA (US); Huilan Han, Woodland, CA (US); Abhinav Bhushan, Sacramento, CA (US)

Correspondence Address: PARK, VAUGHAN & FLEMING LLP, 2820 FIFTH STREET, DAVIS, CA, 95618-7759, US

(73) Assignee: THE REGENTS OF THE UNIVERSITY OF CALIFORNIA, Oakland, CA (US)

(21) Appl. No.: 12/809,890

(22) PCT Filed: Dec. 19, 2008
(86) PCT No.: PCT/US08/87811

§ 371 Date: Jun. 21, 2010

Related U.S. Application Data
(60) Provisional application No. 61/016,310, filed on Dec. 21, 2007.

(30) Foreign Application Priority Data
Dec. 19, 2008 (US) PCT/US2008/087811

(51) Int. Cl. G03F 7/20; C08F 230/04; G03F 7/004; B29C 35/08; B05D 3/12; B05D 1/02; B05D 1/18; B44C 1/22

(52) U.S. Cl. 430/286.1; 526/240; 526/241; 430/325; 264/496; 427/256; 216/49; 977/887

(57) ABSTRACT

One embodiment of the present invention provides a photosensitive organo-metallic hybrid material which functions as both a structural material and a photoresist material. More specifically, this photosensitive organo-metallic hybrid material includes an organo-metallic compound comprised of at least one unsaturated double bond. The photosensitive organo-metallic hybrid material also includes a cross-linking agent comprised of at least two unsaturated double bonds capable of cross-linking the organo-metallic compound to form an organo-metallic hybrid material. Additionally, the photosensitive organo-metallic hybrid material includes a photoactive compound capable of absorbing exposure light during a photolithography process to form the photosensitive organo-metallic hybrid material.

### BACKGROUND

1. Field of the Invention

The present invention generally relates to organo-metallic materials and techniques for using organo-metallic materials for micro- and nanofabrication. More specifically, the present invention relates to techniques for synthesizing organo-metallic polymer and techniques for depositing organo-metallic polymer thin films for micro- and nanofabrication.

2. Related Art

Organo-metallic hybrid materials have been increasingly studied for potential uses in micro- and nanofabrication, partially due to their advantages in organizing both organic and inorganic materials on small length scales. These materials are traditionally deposited on substrates by chemical vapor deposition, atomic layer deposition, or spray pyrolysis. However, these processes are typically associated with high manufacturing costs and high processing temperatures, which limit the potential of the organo-metallic hybrid materials for mass scale production. Hence, there is a need to develop an organo-metallic hybrid material suitable for forming uniform organo-metallic layers on substrates for fabricating micro- and nanostructures and devices without the above-described problems.

In conventional photolithography, design patterns are first transferred from a mask into a photoresist layer on a substrate. The exposed substrate is then etched using wet or dry etching techniques, which transfers the patterns into structural materials underneath the photoresist. The etched patterns are subsequently used to create a resist mold for electroplating, ion implantation or one of the many other post-lithography operations. Because the photoresist layer acts as an etch mask during the etching of the structural material, the material properties of the photoresist become the limiting factor of nearly all of the conventional photolithography applications. Hence, there is a need to develop a lithography technique which does not require using the conventional photoresist and simplifies the conventional photolithography process.

Note that conventional photolithography techniques are generally not suitable for fabricating sub-200 nm feature sizes. In contrast, nano-imprint lithography (NIL) provides a simple, low-cost, and high-throughput method for fabricating nanometer scale features. Typically, an NIL process creates nanoscale patterns by mechanically embossing an imprint resist layer (a counterpart of photoresist in photolithography) using a stamp. During imprinting, the imprint resist is typically cured by heating and/or being exposed to a UV light. Sometimes, the embossed imprint resist is used as an etch mask during a wet or dry etching process, which transfers the nanoscale patterns into structural materials underneath the imprint resist. The conventional imprint resist used in these NIL processes often suffers from poor etch selectivity during the etching process, which ultimately degrades the quality of the nanostructures. Hence, there is a need to develop an imprint resist for the NIL applications without the above-described problems.

### SUMMARY

One embodiment of the present invention provides an organo-metallic hybrid material, which includes an organo-metallic compound comprised of at least one unsaturated double bond, and a cross-linking agent comprised of at least two unsaturated double bonds capable of cross-linking the organo-metallic compound to form the organo-metallic hybrid material.

One embodiment of the present invention provides a photosensitive organo-metallic hybrid material which functions as both a structural material and a photoresist material. More specifically, this photosensitive organo-metallic hybrid material includes an organo-metallic compound comprised of at least one unsaturated double bond. The photosensitive organo-metallic hybrid material also includes a cross-linking agent comprised of at least two unsaturated double bonds capable of cross-linking the organo-metallic compound to form an organo-metallic hybrid material. Additionally, the photosensitive organo-metallic hybrid material includes a photoactive compound capable of absorbing exposure light during a photolithography process to form the photosensitive organo-metallic hybrid material.

One embodiment of the present invention provides a system that patterns organo-metallic nanostructures. During operation, the system obtains an organo-metallic hybrid material. The system then forms a solution of the organo-metallic hybrid material. Next, the system forms a thin film on a substrate using the solution of the organo-metallic hybrid material. The system subsequently patterns organo-metallic nanostructures on the thin film.

One embodiment of the present invention provides a system that performs photolithography. During operation, the system starts by obtaining a solution of a photosensitive organo-metallic hybrid material. The system then forms a thin film on a substrate using the solution of the photosensitive organo-metallic hybrid material, wherein the thin film is photosensitive. Next, the system exposes the thin film with an exposure light, thereby printing patterns onto the thin film. The system subsequently develops the exposed thin film to obtain patterned structures in the thin film. Note that patterning the thin film does not require using an additional photoresist layer or etching the thin film.

One embodiment of the present invention provides a system that patterns microstructures and nanostructures. During operation, the system starts by obtaining a thin film on a substrate, wherein the thin film is photosensitive. The system then patterns a first region of the thin film into microstructures or nanostructures by using a nano-imprint lithography (NIL) process. The system also exposes a second region of the thin film with an exposure light, thereby printing structures onto the second region of the thin film. The system subsequently develops the exposed thin film to obtain patterned structures in the second region of the thin film. Note that patterning the second region of the thin film does not require using an additional photoresist layer or etching the thin film.

### BRIEF DESCRIPTION OF THE FIGURES

FIG. 1 presents a flowchart illustrating a process of patterning microstructures and nanostructures in an organo-metallic film in accordance with an embodiment of the present invention.

FIG. 2 presents a flowchart illustrating a process of synthesizing the solution of the organo-metallic hybrid material in accordance with an embodiment of the present invention.

FIG. 3 illustrates the relationship between the applied spinning speed and the ultimate film thickness of the organo-metallic hybrid film in accordance with an embodiment of the present invention.

FIG. 4 illustrates a process for patterning a photosensitive organo-metallic hybrid thin film without using an additional photoresist layer in accordance with an embodiment of the present invention.

FIG. 5A illustrates a process for directly patterning an organo-metallic hybrid thin film using a nano-imprint lithography (NIL) process in accordance with an embodiment of the present invention.

FIG. 5B illustrates a process for directly patterning an organo-metallic hybrid thin film using an NIL process, wherein the patterned organo-metallic hybrid thin film becomes an etch mask in accordance with an embodiment of the present invention.

Table 1 presents typical synthesis-formulations of the organo-metallic hybrid material (including the solvent) in one embodiment of the present invention.

### DETAILED DESCRIPTION

The following description is presented to enable any person skilled in the art to make and use the invention, and is provided in the context of a particular application and its requirements. Various modifications to the disclosed embodiments will be readily apparent to those skilled in the art, and the general principles defined herein may be applied to other embodiments and applications without departing from the spirit and scope of the present invention. Thus, the present invention is not limited to the embodiments shown, but is to be accorded the widest scope consistent with the claims.

### Formulating an Organo-Metallic Hybrid Material

One embodiment of the present invention provides an organo-metallic hybrid material which includes at least: (1) at least one organo-metallic compound, which is comprised of at least one unsaturated double bond; and (2) at least one cross-linking agent, which is comprised of at least two unsaturated double bonds capable of cross-linking the organo-metallic compound, and other organic materials.

More specifically, the organo-metallic compound includes at least one type of metal which provides the metal source for the organo-metallic hybrid material. In some embodiments, the organo-metallic compound is comprised of more than one type of metal element. In one embodiment, the metal element can include, but is not limited to, ferromagnetic metals, such as nickel (Ni), iron (Fe), and cobalt (Co); paramagnetic metals, such as platinum (Pt); semiconductor materials, such as doped silicon; and other types of metals. Note that the type of metal element in the organo-metallic compound determines the physical properties of the organo-metallic compound. Hence, the type of metal element can be chosen based on desired functionalities of the organo-metallic hybrid material.

Note that the organo-metallic compound can be in a solid form or in a liquid form. Also note that the mass percentage ratio of the organic constituent to the metallic constituent of the organo-metallic compound can be adjusted based on different application requirements. Furthermore, the unsaturated double bond in the organo-metallic compound provides a mechanism to link the organo-metallic compound to the cross-linking agent to form an organo-metallic polymer under certain conditions. This unsaturated double bond can include, but is not limited to, acrylate and methacrylate compounds.

In one embodiment, the cross-linking agent can include any acrylate compounds. In another embodiment, the cross-linking agent can include an aromatic or aliphatic cross-linking agent that reacts with the other ingredients or materials, for example a silsesquioxane oligomer. Note that the cross-linking organic compound can be in a solid form or in a liquid form.

In some embodiments, the organo-metallic hybrid material also includes a silicon-based compound, such as a silicone group. This silicon-based compound is comprised of at least one unsaturated double bond, such as an acrylic functional group, which provides a mechanism to link the silicon-based compound to the cross-linking agent. Note that this silicon-based compound can influence one or more properties of the organo-metallic hybrid material. For example, when the organo-metallic hybrid material is formed into a film on a substrate, this silicon-based compound can affect the lithographic performance and adhesion of the organo-metallic hybrid film. In some embodiments of the present invention, the organo-metallic hybrid material does not have to include a silicon-based compound.

In some embodiments, the organo-metallic hybrid material also includes a photoactive compound. By adding the photoactive compound, the organo-metallic hybrid material becomes photosensitive. This photoactive compound, when exposed to a proper light source, causes the organo-metallic hybrid material to become polymerized. A wide variety of photoactive compounds may be used in the organo-metallic hybrid material to make the material photosensitive including, for example, free radical generators. In general, any photosensitive material that can facilitate photo-polymerization when exposed to an exposure light source may be used as the photoactive compound in the formulation of a “photosensitive” organo-metallic hybrid material.

In one embodiment, the amount of photoactive compound in the photosensitive organo-metallic hybrid material is sufficiently high to facilitate cross-linking of the acrylic components in the photosensitive organo-metallic hybrid material. Typically, the photoactive components can be used in the range of 0.1 to 25%, based on the weight of the composition. In some embodiments, the photoactive component has a weight percentage in the range of 0.1 to 10% in the photosensitive organo-metallic hybrid material. In some embodiments of the present invention, the organo-metallic hybrid material does not have to include a photoactive compound and therefore is not photosensitive. However, both photosensitive and non-photosensitive organo-metallic hybrid materials can be used for microfabrication and nanofabrication, as is described in more detail below.

In one embodiment, the organo-metallic hybrid material is in a solution form. More specifically, an organic solvent with proper solubility parameters to dissolve all of the above-mentioned constituents of the organo-metallic hybrid material is used to form a solution of the organo-metallic hybrid material. Different types of solvents, such as cyclic or straight chain ketones, and ethers can be used. In one embodiment, a solvent containing a multifunctional molecule which can effectively resolve organics, silicons, organo-metallics, and the photo-initiators is used. In another embodiment, a solvent containing a number of co-solvents can be used. For example, propylene glycol methyl ether acetate (PGMEA) may be used to resolve the organo-metallic hybrid material to form the solution.

This solution form of the organo-metallic hybrid material can facilitate depositing the organo-metallic hybrid material on a substrate to form organo-metallic hybrid films. In some embodiments, the solution may be used to coat a substrate using one of the following techniques: spin-coating, spray-coating, and dip-coating. Hence, the solution of the organo-metallic hybrid material is made to have a viscosity range compatible with forming a thin layer of the organo-metallic hybrid material on a substrate using these coating techniques. The viscosity of the solution can be adjusted by controlling the weight ratio of the solvent to the organo-metallic hybrid material. More details of preparing organo-metallic hybrid films from the solution of the organo-metallic hybrid material are described below.

Note that other additives may optionally be included in the formulation of the organo-metallic hybrid material, which can include, but are not limited to, leveling agents, wetting agents, and adhesion promoters. These additives can facilitate depositing organo-metallic hybrid films on the substrates. The amounts of each of these optional additives may be judiciously determined.

Note that when synthesizing the organo-metallic hybrid material, all above-described constituents may be formulated in different weight ratios, and the ratios may be adjusted to meet specific application requirements. Table 1 presents typical synthesis-formulations of the organo-metallic hybrid material (including the solvent) in one embodiment of the present invention. However, other possible synthesis-formulations of the organo-metallic hybrid material can go outside of the ranges listed in Table 1.

Hence, each formulation of the organo-metallic hybrid material includes a set of constituents which are soluble in combination with each other, and form a stable solution, which can be spun-coated, spray-coated, or dip-coated on a substrate.

### Synthesizing an Organo-Metallic Hybrid Film

One embodiment of the present invention provides a technique to deposit organo-metallic films from a solution form of the organo-metallic hybrid material. More specifically, a solution of liable unsaturated double bonds integrated with specific metal and acrylic- or methacrylic-based cross linkers is prepared. These liable unsaturated double bonds can include, but are not limited to, acrylate-containing monomers, methacrylate, oligomer, and polymer. The solution can also contain photoactive compounds, silicon-based compounds, and other functional compounds. Note that mixing different acrylate-based or methacrylate monomers can prevent a rapid reaction of the mixed precursors at the early mixing stage, hence polymerization does not easily occur in the solution.

After formulating the solution, the solution is coated on a substrate based on techniques which can include, but are not limited to, spin-, spray-, or dip-coating. Upon coating, some of the solvent is evaporated using heat and/or vacuum in various combinations. The coating thickness is partially determined by the percentage of solids in the formulation.

After coating, the organo-metallic coating is cured to form an organo-metallic polymeric film. In particular, when the solution contains photoactive compounds, the substrate can be exposed using a broad band or single wavelength (e.g., a UV light). This exposure causes the photoactive compounds to produce free radicals, which then transform the liquid coating into a solid thin film. This results in a homogeneous distribution of the metal particles within the organic matrix to form a uniform organo-metallic film.

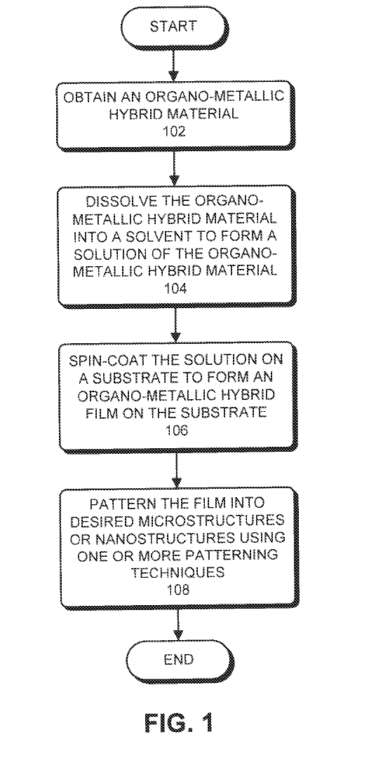

More specifically, FIG. 1 presents a flowchart illustrating a process of patterning microstructures and nanostructures in an organo-metallic film in accordance with an embodiment of the present invention.

The process starts by obtaining an organo-metallic hybrid material (step 102). In one embodiment, the organo-metallic hybrid material contains at least four distinct groups: (1) an organo-metallic compound; (2) a cross-linking organic compound; (3) a photoactive compound; and (4) a silicon-based compound. The functions of each of the groups have been described above.

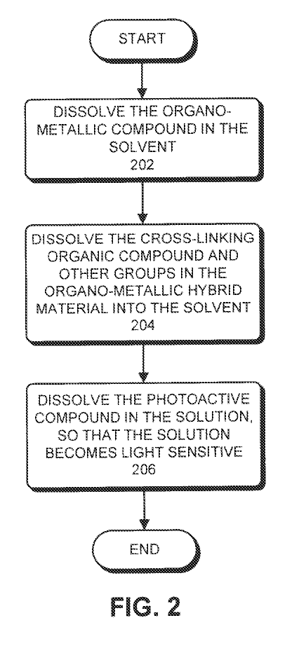

Next, the organo-metallic hybrid material is dissolved into a solvent to form a solution of the organo-metallic hybrid material (step 104). Note that the solvent can be a single solvent or a mixture of a primary solvent and a co-solvent. FIG. 2 presents a flowchart illustrating a process of synthesizing the solution of the organo-metallic hybrid material in accordance with an embodiment of the present invention.

During this synthesizing process, the organo-metallic compound is first dissolved in the solvent (step 202). In some embodiments, one or more co-solvents are used to completely dissolve the organo-metallic compound in the solution. This organo-metallic compound behaves like the precursors to provide the metal sources for the final organo-metallic film. To acquire different physical properties and chemical compositions, multiple organo-metallic compounds of different types can be simultaneously added to the solution. For example, mixing multiple organo-metallic compounds may be useful in generating paramagnetic mixtures of metals.

Next, the cross-linking organic compound and other groups in the organo-metallic hybrid material are added to the solvent, with the exception of the photoactive compound (step 204). Specifically, the cross-linking organic compound facilitates film polymerization when the deposited film is subject to UV exposure. Additionally, the silicon-based compound, such as silyloxyl methacrylate compound, acts as the precursor for providing a silicon dioxide source in the final film. At this stage, the surface level agent and resist glue can be added to the solution to improve film uniformity and film adhesion to the substrate, respectively. Note that the photoactive compound is not added because making the solution photosensitive early is undesirable.

Finally, the photoactive compound, such as the free radical generator, is added to the solution, so that the solution becomes light sensitive, and the final organo-metallic film becomes photo-patternable using a suitable light source (step 206). Note that the exact mass percentage of each chemical group in the solution is variable and the formation can be easily changed and precisely tuned by changing the ratio of these common precursor materials. Furthermore, the solution of the organo-metallic hybrid material is controlled to have a viscosity range similar to the liquid form of a commercial photoresist used for spin-coating a common substrate.

Note that in conventional sol-gel techniques for synthesizing hybrid films, cracks often occur in the films because of the condensation reaction and pore collapse under heat treatment in the colloidal suspension. The solution-synthesizing process of FIG. 2 typically does not cause hydrolysis and a condensation reaction in the synthesized solution, and polymerization does not occur unless the solution is exposed to a specific light source. Hence, the present synthesizing process effectively prevents cracks in the subsequently prepared film which may be caused by stress at the early solution reaction.

In some embodiments of the present invention, the photoactive compound is not included and the solution of the organo-metallic hybrid material is not photosensitive. However, the organo-metallic hybrid film prepared using this non-photosensitive formulation can still be patterned to form organo-metallic microstructures and/or nanostructures. We describe this patterning process without photolithography in more detail below.

Returning to FIG. 1, after synthesizing the solution of the organo-metallic hybrid material, the solution is used to spin-coat a substrate to form an organo-metallic hybrid film on the substrate (step 106). If a photoactive compound is included in the solution, then the spin-coating process forms a photosensitive organo-metallic hybrid film on the substrate. Note that this spin-coating process resembles the way a commercial photoresist is applied to a substrate, which is enabled by the proper viscosity of the solution. The substrate in this process can include, but is not limited to, a silicon wafer, a glass substrate, a specimen substrate, and other types of commonly used or specially designed substrates.

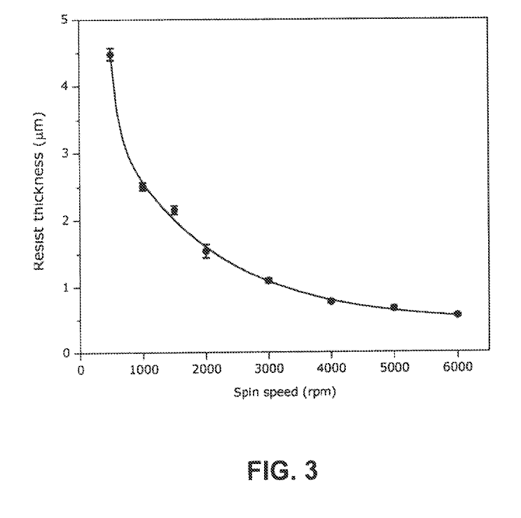

Note that a set of process parameters can be controlled to obtain a desirable thickness of the organo-metallic hybrid film. These process parameters can include, but are not limited to, the spin speed, the duration of the spin, and an annealing temperature. FIG. 3 illustrates the relationship between the applied spinning speed and the ultimate film thickness of the organo-metallic hybrid film in accordance with an embodiment of the present invention.

More specifically, the relationship plot in FIG. 3 was obtained by spinning a solution of the hybrid material directly on a 4-inch silicon wafer at different coating speeds, similar to the conventional photoresist application. As illustrated in FIG. 3, the film thickness varies from 0.5 μm to 4.5 μm as the spinning speed varies from a relatively high speed to a lower speed. This suggests that the hybrid film can be deposited at a specific thickness according to different application requirements, and the desired final height of the organo-metallic microstructures. Note that FIG. 3 is used for demonstration purposes only and should not limit the types of relationship between the organo-metallic film thickness and a range of spinning speed, and should not limit the range of possible film thickness. In fact, much thinner film thicknesses can be obtained by using the present technique.

Furthermore, it is possible to control the thickness of the organo-metallic hybrid film by controlling the weight percentage ratio of the organo-metallic hybrid material to the solvent. For example, increasing the percentage of the organo-metallic hybrid material in the solvent typically facilitates obtaining thicker films, while decreasing the percentage of the organo-metallic hybrid material in the solvent typically facilitates obtaining thinner films. Similarly, to vary film thickness at the same spinning speed, one can adjust the weight ratio of different chemical constituents of the organo-metallic hybrid material, because different chemical constituents can have different viscosities in the formulation.

Note that thermal treatment provides another technique to alter the film thickness. Using this technique, the coated substrate is thermally treated at different temperatures, and different film thicknesses can be obtained by removing different amounts of the residual organic portion of the hybrid film.

Consequently, using the proper composition of the synthesized solution and a controlled spin-coating process, a wide range of organo-metallic hybrid film thicknesses can be obtained. For example, the solution can be used to deposit nanoscale organo-metallic thin films with thicknesses from 1 nm to a few hundred nanometers. Such a thickness range is suitable for patterning nanoscale structures. The solution can be formed into microscale thin films with thicknesses from ˜0.5 μm to ˜10 μm, which is suitable for patterning microscale structures; and into mesoscale films with thicknesses from ˜10 μm to ˜1000 μm, which is suitable for patterning mesoscale structures. In some embodiments, the solution of the organo-metallic hybrid material is formed into macroscale films or bulk materials with thicknesses equal to or greater than 1 mm.

Note that in step 106, the spin-coating operation may be replaced by a spray-coating or a dip-coating operation based on the requirements of the applications. None of these coating techniques require vacuum or sputtering, and therefore all are inexpensive and suitable for low-cost mass-scale production.

In some embodiments, the organo-metallic hybrid film layer can be selectively metallized in specific regions of the film surface, thereby dramatically increasing the metal percentage and conductivity within the selected regions. This can be achieved by removing the organic portion of the film from these regions in the film.

In some embodiments, the organo-metallic hybrid film can be used as an etch mask for the subsequent dry etch (e.g., a plasma etch) or wet etch (e.g., an acid etch) operations. One of the reasons for the etch resistant of the hybrid film is its metal content. In one embodiment, the film may be converted to a metal-doped silicon dioxide layer by using oxygen plasma to remove the organic portion of the film. Alternatively, an organic metal-free silicon-containing film can be obtained by thermally annealing the hybrid film for a predetermined period of time in an oxygen environment.

Note that if the original formulation of the organo-metallic hybrid material does not include a silicon-based compound, removing the organic portion of the film results in a metallized film, which can be used as a high selectivity etch mask under plasma conditions. Note that this metallized film may be highly conductive. In some embodiments, a selectivity of this etch mask layer is tunable by controlling a ratio of the metal content to the remaining organic content in the organo-metallic hybrid film, or by carefully choosing the metal types.

In some embodiments of the present invention, the cured organo-metallic hybrid film becomes chemically resistant to one or more of the following etchants: hydrochloric acid; hydrofluoric acid; nitric and concentrated sulfuric acid (Piranha etch); CHF₃, CF₄, or SF₆ gas, and other wet or dry etchants. Note that such a chemical stability is not observed using conventional resist formulations.

Continuing with FIG. 1, after forming the layer of organo-metallic hybrid film on a substrate, the film is patterned into the desired microstructures or nanostructures using one or more patterning techniques (step 108). We describe different patterning techniques below.

### Simplified Photolithography Process

For a photosensitive organo-metallic hybrid film formed in the above-described process, the hybrid film can be directly patterned and developed into microstructures or nanostructures through a simplified photolithography process without using an additional photoresist layer.

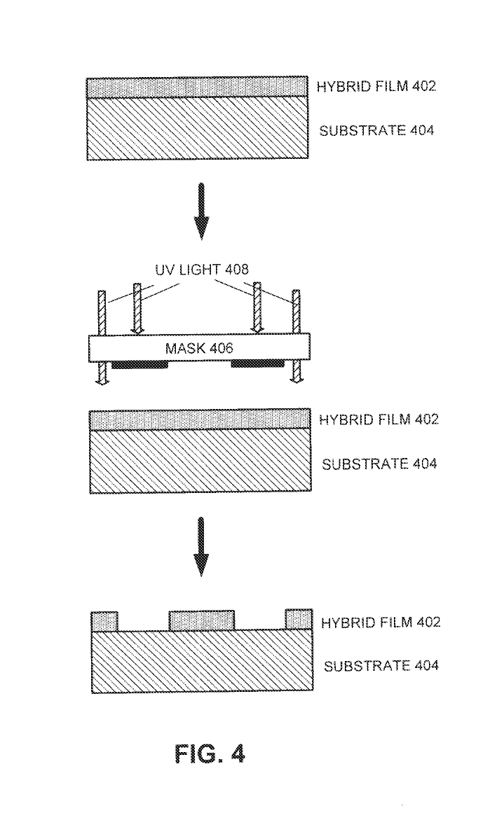

FIG. 4 illustrates a process for patterning a photosensitive organo-metallic hybrid thin film 402 without using an additional photoresist layer in accordance with an embodiment of the present invention.

As seen in FIG. 4, the process starts by receiving a photosensitive organo-metallic hybrid film 402 containing a photoactive compound, which is coated on a substrate 404. Note that for hybrid film 402, the choice of substrate 404 should not affect the subsequent imaging process and patterning results. Substrate 404 can include silicon, plastic, aluminum, and glass, among others.

Next, photosensitive hybrid film 402 is exposed to an exposure light, such as UV light 408, through a photomask 406, which transfers the images of photomask 406 to photosensitive hybrid film 402. Note that the UV exposure causes polymerization of the photosensitive hybrid film 402, which transforms the liquid monomers in the hybrid film 402 into a solid thin film. More specifically, photosensitive hybrid film 402 comprised of the organic cross-linking mixture, upon exposure, will cure to a network consisting of metal particles, carbon, and silicon. In some cases, a post-exposure bake is needed to complete the cross-linking process and to minimize standing wave effects. The amount of energy required to fully expose the organo-metallic hybrid film depends on the formulation, bake conditions and other lithographic parameters.

Note that although a bright-field photomask is shown in FIG. 4, generally, both bright field and dark-field photomasks can be used to expose the photosensitive hybrid film.

After exposure, photosensitive hybrid film 402 is developed and patterned into microstructures or nanostructures according to the designs of mask 406. Note that different developers may be used, including but not limited to, acetone, n-propanol, isopropanol, methanol, water, or mixtures thereof.

Note that during the above-described photolithography process, photosensitive organo-metallic hybrid film 402 acts as both a photoresist and a structural layer. The imageable property of the film is the result of the photoactive compound, and the patternable/structural property is due to the other constituents, such as the metal particles, carbon, and silicon. This photolithography process directly images and patterns a film layer without using an additional photoresist, thereby simplifying the process flow. From a device fabrication perspective, this directly patternable property also simplifies subsequent etching and other post-lithography process steps. Although we illustrate photosensitive hybrid film 402 as a negative photoresist, photosensitive hybrid film 402 can also be synthesized to behave as a positive photoresist.

Note that it is possible to use the above-described photolithography process to define microstructures and even sub-micron structures. However, it becomes difficult to use this technique to fabricate sub-200 nm feature sizes.

### Direct Patterning Using Nano-imprint Lithography (NIL)

Nano-imprint lithography (NIL) provides a simple, low-cost, and high-throughput method for fabricating nanometer scale features. One embodiment of the present invention uses an NIL process to directly pattern an organo-metallic hybrid film prepared in accordance with the process of FIG. 1.

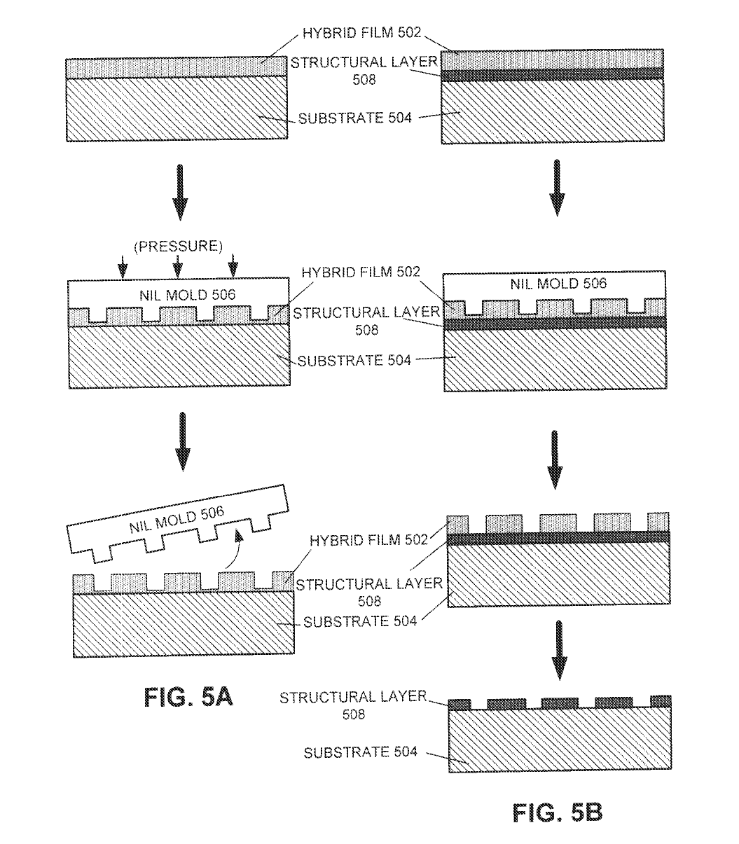

FIG. 5A illustrates a process for directly patterning an organo-metallic hybrid thin film 502 using an NIL process in accordance with an embodiment of the present invention.

As seen in FIG. 5A, the process starts by receiving an organo-metallic hybrid film 502, which is coated on a substrate 504. Note that organo-metallic hybrid film 502 includes at least an organo-metallic compound and a cross-linking organic compound. In one embodiment, organo-metallic hybrid film 502 includes a photoactive compound. In another embodiment, organo-metallic hybrid film 502 does not include a photoactive compound.

Next, an NIL mold 506, which has predefined topological patterns, is brought into contact with organo-metallic hybrid film 502, and a pressing process (which may require heating) stamps the patterns on NIL mold 506 into organo-metallic hybrid film 502. Hence, the feature sizes in the patterned organo-metallic hybrid film 502 are determined by the patterns on NIL mold 506, which can include both microstructures and nanostructures.

NIL mold 506 is separated from the patterned organo-metallic hybrid film 502. Note that there may be residual materials left in the bottom of the holes in the patterned organo-metallic hybrid film 502. Typically, these residual materials are undesirable and need to be removed, which requires an additional dry etch or etch step. Note that because of the above-described chemical resistant property, the patterned organo-metallic hybrid film 502 becomes a natural etch mask for the “de-scum” operation without having to deposit an additional layer of etch mask on the patterned film. In one embodiment, prior to performing the de-scum operation, the patterned organo-metallic hybrid film 502 is cured to remove the organic portion of the material.

FIG. 5B illustrates a process for directly patterning an organo-metallic hybrid thin film 502 using an NIL process, wherein the patterned organo-metallic hybrid thin film 502 becomes an etch mask in accordance with an embodiment of the present invention.

As seen in FIG. 5B, a structure layer 508 is added between organo-metallic hybrid thin film 502 and substrate 504. An NIL process then patterns organo-metallic hybrid film 502 in the same manner as in FIG. 5A. After lifting off NIL mold 506, patterned organo-metallic hybrid film 502 becomes an etch mask for structure layer 508, and a pattern transfer process (e.g., a reactive ion etching process) can be used to transfer the pattern in the organo-metallic hybrid film 502 to the structure layer 508 beneath. Note that for patterns with dimensions less than ˜200 nm, and a structure layer 508 made of conventional etch masks typically do not provide sufficiently high selectivity for etching such nanostructures into the metal layer. Because of the chemical resistance property due to its metal content, the patterned organo-metallic hybrid film 502 becomes a high selectivity etch mask when such high selectivity is required. In one embodiment, prior to performing the etching operation, the patterned organo-metallic hybrid film 502 is cured to remove the organic portion of the material.

Note that the patterned thin metal-containing layers, such as the patterned hybrid film 502 in FIG. 5A and the patterned structure layer 508 in FIG. 5B, can be used as a substrate layer for electrodepositing “shells” of metals on top of the nanostructures that have been created during the corresponding NIL processes. This is because the patterned hybrid layers containing metal can be conductive, which facilitates depositing other metal on top of them by electro-depositing.

One application of this shell metal deposition is for the patterned media in high density magnetic data storage. More specifically, to fabricate this patterned media, a thin magnetic “shell” is electro-deposited onto existing metal-containing nanostructures in the presence of an external magnetic field. This way, the final nanostructures attain the preferred magnetic properties provided by the “shell.” In one embodiment, this magnetic shell material can include, but is not limited to, Ni, Fe, Co, metal alloys, and other ferromagnetic or paramagnetic materials.

Note that the above-described processes provide simplified techniques for fabricating metallic nanostructures which can have both conductive and magnetic properties. In addition, these processes can be extended to depositing multiple materials to achieve tailored compositions and alloys. These materials can be processed into a wide range of structures including nano-dots, nano-wires, nano-posts, nano-width lines, and other nanostructures. Note that these nanofabricating techniques typically do not require vacuum deposition or a cleanroom environment.

Combining a Photolithography Process and an NIL process

One embodiment of the present invention provides a technique for fabricating both microstructures and nanostructures within a same photosensitive organo-metallic hybrid film. During operation, the system receives a photosensitive organo-metallic hybrid thin film on a substrate. The system then patterns a first region of the photosensitive organo-metallic hybrid thin film using an NIL process to create nanostructures in the first regions.

Separately, the system exposes a second region of the photosensitive organo-metallic hybrid thin film with an exposure light (such as a UV light), thereby printing structures onto the second region of the photosensitive thin film. Next, the system develops the exposed photosensitive thin film to obtain patterned structures in the second region of the photosensitive thin film. Note that performing photolithography on the second region of the photosensitive thin film does not require using an additional photoresist layer or etching the photosensitive polymeric thin film. Note that by integrating the NIL process and the photolithography process on the same thin film surface, the system allows different feature sizes to be combined on the same surface.

### Other Applications

The photosensitive organo-metallic hybrid film as described above can be formed into a wide range of functional structures. These functional structures can include, but are not limited to: an optical structure; a waveguide structure; a solar cell structure; a magnetic structure; a biochemical structure; a biomedical structure; an electrical, radiation, or insulation layer based on the properties of the metal used in cross-linked polymer backbone formed upon processing; and other structures which require a metal constituent.

Note that for a solar cell application, the entire surface of a photosensitive organo-metallic hybrid film may be used as a solar cell without the need for an imaging or patterning process.

### An Example of Synthesizing Organo-Metallic Hybrid Materials

In one example, to synthesize organo-metallic hybrid film containing metal lead, Pb(II) Acrylate at 1.4 wt % from Gelest Inc. was dissolved in 2-Methoxyethanol (at 28 wt %, Sigma-Aldrich) in a brown bottle with a magnetic stirrer for 5 minutes or until the solution was completely clear. 3-(Trimethoxysilyl) propyl methacrylate (TMOME) at 28 wt % from Aldrich, Trimethylolpropane about 27 wt % from Sigma-Aldrich, and less than 5 wt % 3-Aminopropyl-triethoxysilane and PolyFox TB are then added to the Pb(II) Acrylate solution. The solution was synthesized at room temperature with stirring until it became completely clear. Under yellow light, Irgacure 2022 (at 12 wt %, Ciba) photoactive compound was added to the mixture. The resulting solution remained transparent. No phase separation or instability was observed for extended period of time.

### An Exemplary Film Deposition and Pattern Process

In one example, film deposition is conducted by simple spin-coating. Spin-coating and the photolithography process were carried out in a class 100 clean room. 4-inch silicon wafers (<100> orientation, University Wafer) were used as the hybrid film substrate. The solution was filtered by 0.1 μm Whatman filter before coating and no adhesion promoter was required. After coating, the soft baked wafer was exposed in a MA4-Karl Suss Mask Aligner using a binary resolution mask followed by a post exposure bake. Exposure time varied as a function of film thickness at an exposure setting of 22 mW/cm² using an i-line filter. This specific hybrid film is a negative tone photoresist and the exposure area is cross-linked after UV exposure. A number of different solvents were employed to develop the cross-linked images. Methanol or a combination of Methanol and Isopropyl alcohol were used in most cases. Depending on the solvent(s) used, the develop time varied from 15 seconds to several minutes.

The foregoing descriptions of embodiments of the present invention have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention. The scope of the present invention is defined by the appended claims.

TABLE 1

| | Chemical | Mass |
|---|---|---|
| Material | category | Percent |
| Organo-metallic | Metal source | 5-40 |
| compounds | | |
| Acrylate or | Cross-linker | 20-40 |
| methacrylate | | |
| compounds | | |
| Photoactive | Photo-initiator | 2-10 |
| compounds | | |
| Organic | Solvent | 2-80 |
| solvent(s) | | |
| Silyloxyl | SiO2 source | 0-50 |
| methacrylates | | |
| Silyloxyl or other | Resist glue | 0-5 |
| resist adhesion | | |
| promoters | | |

1.-96. (canceled)

97. An organo-metallic hybrid material, comprising:
at least one organo-metallic compound comprised of at least one unsaturated double bond; and
at least one cross-linking agent comprised of at least two unsaturated double bonds capable of cross-linking the organo-metallic compound to form the organo-metallic hybrid material.

98. The organo-metallic hybrid material of claim 97, wherein the organo-metallic hybrid material is optically transparent.

99. The organo-metallic hybrid material of claim 97, wherein the unsaturated double bond can include acrylate or methacrylate compounds.

100. The organo-metallic hybrid material of claim 97, wherein the cross-linking agent can include:
a silsesquioxane oligomer; and
any other suitable aromatic or aliphatic cross-linking agent.

101. The organo-metallic hybrid material of claim 97, wherein the types of metal in the organo-metallic compound can include:
ferromagnetic metals;
paramagnetic metals;
semiconductor materials; and
other types of metals.

102. A photosensitive organo-metallic hybrid material which functions as both a structural material and a photoresist material, comprising:
an organo-metallic compound comprised of at least one unsaturated double bond;
a cross-linking agent comprised of at least two unsaturated double bonds capable of cross-linking the organo-metallic compound to form an organo-metallic hybrid material; and
a photoactive compound capable of absorbing exposure light during a photolithography process to form the photosensitive organo-metallic hybrid material.

103. The photosensitive organo-metallic hybrid material of claim 102, wherein the photosensitive organo-metallic hybrid material is formed into a thin film on a substrate using a deposition process, wherein the thin film is imageable.

104. The photosensitive organo-metallic hybrid material of claim 103, wherein the thin film, upon curing, acts as an etch mask layer during an etching process, wherein a selectivity of the etch mask layer is tunable and is determined in part by a ratio of the metal content to the organic content in the photosensitive organo-metallic hybrid material, and the metal type.

105. The photosensitive organo-metallic hybrid material of claim 103, wherein the thin film is cured through a curing process, wherein the cured thin film is chemically resistant to:
hydrochloric acid;
hydrofluoric acid;
nitric acid;
concentrated sulfuric acid;
CHF₃, CF₄, or SF₆ plasma (reactive ion etching) gas; and
other wet or dry etchants.

106. The photosensitive organo-metallic hybrid material of claim 102, wherein the types of metal in the organo-metallic compound can include:
ferromagnetic metals;
paramagnetic metals;
semiconductor materials; and
other types of metals.

107. A method for patterning organo-metallic nanostructures, comprising:
obtaining an organo-metallic hybrid material;
forming a solution of the organo-metallic hybrid material;
forming a thin film on a substrate using the solution of the organo-metallic hybrid material; and
patterning organo-metallic nanostructures on the thin film.

108. The method of claim 107, wherein forming the thin film on the substrate involves using one of the following coating processes to coat a solution of the organo-metallic hybrid material on the substrate:
spin-coating;
spray-coating; and
dip-coating.

109. The method of claim 107, wherein the method further comprises curing the patterned organo-metallic nanostructures, so that the cured and patterned organo-metallic nanostructures act as an etch mask layer during an etching process, wherein a selectivity of the etch mask layer is tunable and is determined in part by a ratio of the metal content to the organic content in the organo-metallic hybrid material, and the metal type.

110. The method of claim 107, wherein the method further comprises metallizing the patterned organo-metallic nanostructures by removing the organic contents of the patterned organo-metallic nanostructures.

111. The method of claim 107, further comprising synthesizing the organo-metallic hybrid material by formulating:
an organo-metallic compound comprised of at least one unsaturated double bond; and
a cross-linking agent comprised of at least two acrylic functional groups capable of cross-linking the organo-metallic compound to form an organo-metallic hybrid material.

112. A method for performing photolithography, comprising:
obtaining a solution of a photosensitive organo-metallic hybrid material;
forming a thin film on a substrate using the solution of the photosensitive organo-metallic hybrid material, wherein the thin film is photosensitive;
exposing the thin film with an exposure light, thereby printing patterns onto the thin film; and
developing the exposed thin film to obtain patterned structures in the thin film;
wherein patterning the thin film does not require using an additional photoresist layer or etching the thin film.

113. The method of claim 112, wherein the photosensitive organo-metallic hybrid material functions as both a structural material and a photoresist material.

114. The method of claim 112, wherein the method further comprises curing the patterned structures, so that the cured and patterned structures act as an etch mask layer during an etching process, wherein a selectivity of the etch mask layer is tunable and is determined in part by a ratio of the metal content to the organic content in the photosensitive organo-metallic hybrid material, and the metal type.

115. The method of claim 112, wherein the method further comprises metallizing the patterned structures by removing the organic contents of the patterned structures.

116. The method of claim 112, further comprising synthesizing the photosensitive organo-metallic hybrid material by formulating:
an organo-metallic compound comprised of at least one unsaturated double bond;
a cross-linking agent comprised of at least two acrylic functional groups capable of cross-linking the organo-metallic compound to form an organo-metallic hybrid material; and
a photoactive material capable of absorbing exposure light during a photolithography process to form the photosensitive organo-metallic hybrid material.

117. A method for patterning microstructures and nanostructures, comprising:
obtaining a thin film on a substrate, wherein the thin film is photosensitive;
patterning a first region of the thin film into microstructures or nanostructures by using a nano-imprint lithography (NIL) process;
exposing a second region of the thin film with an exposure light, thereby printing structures onto the second region of the thin film; and
developing the exposed thin film to obtain patterned structures in the second region of the thin film;
wherein patterning the second region of the thin film does not require using an additional photoresist layer or etching the thin film.

118. The method of claim 117, wherein the photosensitive hybrid material functions as both a structural material and a photoresist material.
